(19) United States
(12) Patent Application Publication
(10) Pub. No.: US 2026/0165187 A1
(43) Pub. Date: Jun. 11, 2026

(54) ELECTRONIC COMPONENT ENCAPSULATION

(71) Applicant: Analog Devices, Inc., Wilmington, MA (US)

(72) Inventors: Mark Downey, Bolton, MA (US); Hansong Zeng, Lowell, MA (US); David Frank Bolognia, Charlestown, MA (US)

(21) Appl. No.: 18/972,691

(22) Filed: Dec. 6, 2024

(51) Int. Cl. H01L 23/31; H01L 21/56; H01L 23/053; H01L 23/06

(52) U.S. Cl. CPC H10W 74/114; H10W 74/016; H10W 76/15; H10W 76/17

(57) ABSTRACT

An encapsulated integrated circuit package is disclosed. The package includes an integrated device package mounted on a substrate. The integrated device package may have a housing defining a cavity and a crystal oscillator in the cavity. The integrated device package may be encapsulated using a high-pressure molding process. The integrated circuit package may further comprise a protection layer over the integrated device package to reduce deformation during pressure processes.

### BACKGROUND

### Field

The field relates generally to printed circuit board assemblies (PCBA) encapsulation, and, more particularly, to the protection of an integrated device package on a substrate from stress and deformation during injection molding.

### Description of the Related Art

Injection molding plastics over integrated device packages is an effective way to protect the assembly against different environmental exposures. However, these encapsulation processes can expose commonly used pressure-sensitive integrated device packages to high pressure and result in deformation and damage. For example, electronic modules with crystal oscillators are easily damaged during injection molding with molding pressures above 1000 PSI. Accordingly, there remains a continuing need for improved packaging techniques.

### SUMMARY

In some aspects, the techniques described herein relate to a method for manufacturing an integrated circuit package, the method including: providing a substrate; providing an integrated device package mounted to the substrate; and forming a protection layer at least partially over the integrated device package by applying a first liquid to the integrated device package and hardening the first liquid at a first pressure less than 1000 psi relative to an atmospheric pressure.

In some aspects, the techniques described herein relate to a method, wherein the method further includes forming an encapsulant at least partially over the protection layer at a second pressure higher than the first pressure.

In some aspects, the techniques described herein relate to a method, wherein forming the encapsulant includes forming the encapsulant using injection molding.

In some aspects, the techniques described herein relate to a method, wherein the second pressure is at least 1000 psi above an atmospheric pressure.

In some aspects, the techniques described herein relate to a method, wherein forming the protection layer further includes attaching a solid element to the integrated device package using the first liquid, wherein the solid element has a higher Young's modulus than that of the hardened first liquid.

In some aspects, the techniques described herein relate to a method, wherein the integrated device package includes a housing defining a cavity.

In some aspects, the techniques described herein relate to a method, wherein the housing defines the cavity around a piezoelectric oscillator configured to output a periodic electrical signal.

In some aspects, the techniques described herein relate to an integrated circuit package, including: a substrate; an integrated device package mounted to the substrate; and a protection layer disposed at least partially over the integrated device package, the protection layer including a solid element attached to the integrated device package at a first pressure.

In some aspects, the techniques described herein relate to an integrated circuit package, further including an encapsulant disposed at least partially over the protection layer, the encapsulant formed at a second pressure higher than the first pressure.

In some aspects, the techniques described herein relate to an integrated circuit package, wherein the solid element is planar shaped.

In some aspects, the techniques described herein relate to an integrated circuit package, wherein the protection layer further includes a first liquid applied to the integrated device package and hardened at the first pressure, wherein the first liquid is configured to attach the solid element to the integrated device package.

In some aspects, the techniques described herein relate to an integrated circuit package, wherein the solid element has a higher Young's modulus than that of the hardened first liquid.

In some aspects, the techniques described herein relate to an integrated circuit package, wherein the solid element includes a ceramic, a semiconductor, or silicon.

In some aspects, the techniques described herein relate to an integrated circuit package, wherein an area of the solid element is at least 30% of an area of the integrated device package.

In some aspects, the techniques described herein relate to an integrated circuit package, wherein the encapsulant is configured to form a water-tight or a gas-tight barrier over the integrated device package.

In some aspects, the techniques described herein relate to an integrated circuit package, wherein the integrated device package includes a housing defining a cavity.

In some aspects, the techniques described herein relate to an integrated circuit package, wherein the housing defines the cavity around a piezoelectric oscillator configured to output a periodic electrical signal.

In some aspects, the techniques described herein relate to an integrated circuit package, wherein a thickness of the housing is less than 1 mm.

In some aspects, the techniques described herein relate to an integrated circuit package, including: a substrate; an integrated device package mounted to the substrate; and a protection layer disposed at least partially over the integrated device package, the protection layer including a first component, wherein the first component includes a first material, wherein the first material has a flowable state in which the first material is configured to flow over the integrated device package at a first pressure, wherein the first material further includes a hardened state formed by hardening the flowable state at the first pressure, and wherein the first component includes the first material in the hardened state; and an encapsulant formed at least partially over the protection layer at a second pressure higher than the first pressure.

In some aspects, the techniques described herein relate to an integrated circuit package, wherein the protection layer further includes a second component, the second component including a second solid material attached to the integrated device package at the first pressure using the first material.

In some aspects, the techniques described herein relate to a method for manufacturing an integrated circuit package, the method including: providing a substrate; providing an integrated device package mounted to the substrate; forming a protection layer at least partially over the integrated device package by applying a first liquid to the integrated device package and hardening the first liquid at a first pressure; and forming an encapsulant at least partially over the protection layer at a second pressure higher than the first pressure.

In some aspects, the techniques described herein relate to a method, wherein, when forming the encapsulant, the protection layer reduces pressure or stress that may otherwise be experienced by the integrated device package.

In some aspects, the techniques described herein relate to a method, wherein, when forming the encapsulant, a maximum pressure experienced by the integrated device package is less than 20% of the second pressure.

In some aspects, the techniques described herein relate to a method, wherein the first pressure is lower than 1000 psi above an atmospheric pressure.

In some aspects, the techniques described herein relate to a method, wherein the first pressure is lower than 5000 psi above an atmospheric pressure.

In some aspects, the techniques described herein relate to a method, wherein the first pressure is lower than 10000 psi above an atmospheric pressure.

In some aspects, the techniques described herein relate to a method, wherein the first pressure is an atmospheric pressure.

In some aspects, the techniques described herein relate to a method, wherein forming the encapsulant includes forming the encapsulant using injection molding.

In some aspects, the techniques described herein relate to a method, wherein the second pressure is at least 1000 psi above an atmospheric pressure.

In some aspects, the techniques described herein relate to a method, wherein the second pressure is at least 5000 psi above an atmospheric pressure.

In some aspects, the techniques described herein relate to a method, wherein the second pressure is at least 10000 psi above an atmospheric pressure.

In some aspects, the techniques described herein relate to a method, wherein the protection layer and the encapsulant include different materials.

In some aspects, the techniques described herein relate to a method, wherein the protection layer separates the integrated device package from the encapsulant such that the integrated device package does not directly contact the encapsulant.

In some aspects, the techniques described herein relate to a method, wherein the integrated device package is in direct contact with both the protection layer and the encapsulant.

In some aspects, the techniques described herein relate to a method, wherein the substrate is mounted to a bottom side of the integrated device package, and the protection layer is formed at least partially over a top side of the integrated device package.

In some aspects, the techniques described herein relate to a method, wherein the protection layer is formed to completely cover the top side of the integrated device package.

In some aspects, the techniques described herein relate to a method, further including forming the protection layer at least partially over the substrate.

In some aspects, the techniques described herein relate to a method, further including forming the encapsulant at least partially over the substrate.

In some aspects, the techniques described herein relate to a method, wherein the first liquid is an epoxy, a gel, an adhesive, a plastic, a sealant, or a potting material.

In some aspects, the techniques described herein relate to a method, wherein applying the first liquid includes applying the first liquid directly to an external surface of the integrated device package.

In some aspects, the techniques described herein relate to a method, wherein applying the first liquid further includes applying the first liquid directly to an external top surface of the integrated device package.

In some aspects, the techniques described herein relate to a method, wherein the first liquid is Hysol® FP4450HF sold by LOCTITE®.

In some aspects, the techniques described herein relate to a method, wherein the protection layer includes a smooth, convex exterior profile defined by a surface tension of the first liquid.

In some aspects, the techniques described herein relate to a method, wherein the protection layer forms a droplet around the integrated device package.

In some aspects, the techniques described herein relate to a method, wherein hardening the first liquid includes curing the first liquid through cooling, heating, drying, light exposure, chemical bonding, or cross-linking process.

In some aspects, the techniques described herein relate to a method, wherein forming the protection layer further includes hardening a second liquid different than the first liquid.

In some aspects, the techniques described herein relate to a method, wherein forming the protection layer further includes attaching a solid element to the integrated device package using the first liquid, wherein the solid element has a higher Young's modulus than that of the hardened first liquid.

In some aspects, the techniques described herein relate to a method, wherein the solid element is flat or planar shaped.

In some aspects, the techniques described herein relate to a method, wherein the solid element includes a ceramic, a semiconductor, a plastic, or silicon.

In some aspects, the techniques described herein relate to a method, wherein an area of the solid element is equal or larger than the area of the integrated device package.

In some aspects, the techniques described herein relate to a method, wherein an area of the solid element is at least 30% of an area of the integrated device package.

In some aspects, the techniques described herein relate to a method, wherein attaching the solid element includes attaching the solid element in direct contact with the integrated device package.

In some aspects, the techniques described herein relate to a method, wherein the solid element is attached to the integrated device package with a portion of the first liquid between the solid element and the integrated device package.

In some aspects, the techniques described herein relate to a method, wherein the encapsulant includes polypropylene.

In some aspects, the techniques described herein relate to a method, wherein the encapsulant forms a water-tight or a gas-tight barrier over the integrated device package.

In some aspects, the techniques described herein relate to a method, wherein the encapsulant includes a biocompatible material.

In some aspects, the techniques described herein relate to a method, wherein the integrated device package includes a housing defining a cavity.

In some aspects, the techniques described herein relate to a method, wherein the housing defines the cavity around an oscillator configured to output a periodic electrical signal.

In some aspects, the techniques described herein relate to a method, wherein the oscillator includes a piezoelectric resonator.

In some aspects, the techniques described herein relate to a method, wherein the oscillator includes quartz.

In some aspects, the techniques described herein relate to a method, wherein the oscillator is disposed in parallel and immediately adjacent to a side of the housing.

In some aspects, the techniques described herein relate to a method, wherein the oscillator is disposed in parallel and directly underneath a top side of the housing.

In some aspects, the techniques described herein relate to a method, wherein the oscillator includes a thin planar shape.

In some aspects, the techniques described herein relate to a method, wherein the oscillator is suspended in the cavity using one or more supports protruding from a substrate.

In some aspects, the techniques described herein relate to a method, wherein the housing includes a metal.

In some aspects, the techniques described herein relate to a method, wherein the housing includes aluminum.

In some aspects, the techniques described herein relate to a method, wherein the housing includes contact pads electrically connected to the substrate.

In some aspects, the techniques described herein relate to a method, wherein the housing further includes insulating portions separating the contact pads.

In some aspects, the techniques described herein relate to a method, wherein a thickness of the housing is less than 1 mm.

In some aspects, the techniques described herein relate to a method, wherein a thickness of the housing is less than 0.5 mm.

In some aspects, the techniques described herein relate to an integrated circuit package, including: a substrate; an integrated device package mounted to the substrate; a protection layer disposed at least partially over the integrated device package, the protection layer including a first liquid applied to the integrated device package and hardened at a first pressure; and an encapsulant disposed at least partially over the protection layer, the encapsulant formed at a second pressure higher than the first pressure.

In some aspects, the techniques described herein relate to an integrated circuit package, wherein the protection layer is configured to absorb or disperse pressure or stress away from the integrated device package.

In some aspects, the techniques described herein relate to an integrated circuit package, wherein the first pressure is lower than 100 psi above an atmospheric pressure.

In some aspects, the techniques described herein relate to an integrated circuit package, wherein the first pressure is lower than 500 psi above an atmospheric pressure.

In some aspects, the techniques described herein relate to an integrated circuit package, wherein the first pressure is lower than 1000 psi above an atmospheric pressure.

In some aspects, the techniques described herein relate to an integrated circuit package, wherein the first pressure is an atmospheric pressure.

In some aspects, the techniques described herein relate to an integrated circuit package, wherein the encapsulant is formed using injection molding.

In some aspects, the techniques described herein relate to an integrated circuit package, wherein a maximum thickness of the encapsulant is less than 1 mm.

In some aspects, the techniques described herein relate to an integrated circuit package, wherein a maximum thickness of the encapsulant is less than 2 mm.

In some aspects, the techniques described herein relate to an integrated circuit package, wherein a maximum thickness of the encapsulant is less than 4 mm.

In some aspects, the techniques described herein relate to an integrated circuit package, wherein the second pressure is higher than 1000 psi above an atmospheric pressure.

In some aspects, the techniques described herein relate to an integrated circuit package, wherein the second pressure is higher than 5000 psi above an atmospheric pressure.

In some aspects, the techniques described herein relate to an integrated circuit package, wherein the second pressure is higher than 10000 psi above an atmospheric pressure.

In some aspects, the techniques described herein relate to an integrated circuit package, wherein the protection layer and the encapsulant include different materials.

In some aspects, the techniques described herein relate to an integrated circuit package, wherein the protection layer separates the integrated device package from the encapsulant such that the integrated device package does not directly contact the encapsulant.

In some aspects, the techniques described herein relate to an integrated circuit package, wherein a bottom side of the integrated device package is mounted to the substrate, and a top side of the integrated device package is at least partially covered by the protection layer.

In some aspects, the techniques described herein relate to an integrated circuit package, wherein a top side of the integrated device package is completely covered by the protection layer.

In some aspects, the techniques described herein relate to an integrated circuit package, wherein the integrated device package is in direct contact with both the protection layer and the encapsulant.

In some aspects, the techniques described herein relate to an integrated circuit package, wherein the protection layer is disposed at least partially over the substrate.

In some aspects, the techniques described herein relate to an integrated circuit package, wherein the encapsulant is disposed at least partially over the substrate.

In some aspects, the techniques described herein relate to an integrated circuit package, wherein the first liquid is an epoxy, a gel, an adhesive, a plastic, a sealant, or a potting material.

In some aspects, the techniques described herein relate to an integrated circuit package, wherein the first liquid is in direct contact with an external surface of the integrated device package.

In some aspects, the techniques described herein relate to an integrated circuit package, wherein the first liquid is in direct contact with an external top surface of the integrated device package.

In some aspects, the techniques described herein relate to an integrated circuit package, wherein the first liquid is Hysol® FP4450HF sold by LOCTITE®.

In some aspects, the techniques described herein relate to an integrated circuit package, wherein the protection layer includes a smooth, convex exterior profile defined by a surface tension of the first liquid.

In some aspects, the techniques described herein relate to an integrated circuit package, wherein the protection layer forms a droplet around the integrated device package.

In some aspects, the techniques described herein relate to an integrated circuit package, wherein the first liquid is hardened through cooling, heating, drying, light exposure, or a chemical bonding process.

In some aspects, the techniques described herein relate to an integrated circuit package, wherein the protection layer further includes a second liquid different than the first liquid.

In some aspects, the techniques described herein relate to an integrated circuit package, wherein the protection layer further includes a solid element attached to the integrated device package using the first liquid, wherein the solid element has a higher Young's modulus than that of the hardened first liquid.

In some aspects, the techniques described herein relate to an integrated circuit package, wherein the solid element is flat or planar shaped.

In some aspects, the techniques described herein relate to an integrated circuit package, wherein the solid element includes a ceramic, a semiconductor, or silicon.

In some aspects, the techniques described herein relate to an integrated circuit package, wherein an area of the solid element is approximately equal to or larger than the area of the integrated device package.

In some aspects, the techniques described herein relate to an integrated circuit package, wherein an area of the solid element is at least 30% of an area of the integrated device package.

In some aspects, the techniques described herein relate to an integrated circuit package, wherein the solid element is attached in direct contact with the integrated device package.

In some aspects, the techniques described herein relate to an integrated circuit package, wherein the solid element is attached to the integrated device package with a portion of the first liquid between the solid element and the integrated device package.

In some aspects, the techniques described herein relate to an integrated circuit package, wherein the encapsulant includes polypropylene.

In some aspects, the techniques described herein relate to an integrated circuit package, wherein the encapsulant is configured to form a water-tight or a gas-tight barrier over the integrated device package.

In some aspects, the techniques described herein relate to an integrated circuit package, wherein the encapsulant includes a biocompatible material.

In some aspects, the techniques described herein relate to an integrated circuit package, wherein the integrated device package includes a housing defining a cavity.

In some aspects, the techniques described herein relate to an integrated circuit package, wherein the housing defines the cavity around an oscillator configured to output a periodic electrical signal.

In some aspects, the techniques described herein relate to an integrated circuit package, wherein the oscillator includes a piezoelectric resonator.

In some aspects, the techniques described herein relate to an integrated circuit package, wherein the oscillator includes quartz.

In some aspects, the techniques described herein relate to an integrated circuit package, wherein the oscillator is disposed in parallel to a side of the housing, immediately adjacent to the side of the housing.

In some aspects, the techniques described herein relate to an integrated circuit package, wherein the oscillator is disposed in parallel and immediately adjacent to a side of the housing.

In some aspects, the techniques described herein relate to an integrated circuit package, wherein the oscillator is disposed in direct contact with the housing.

In some aspects, the techniques described herein relate to an integrated circuit package, wherein the oscillator includes a thin planar shape.

In some aspects, the techniques described herein relate to an integrated circuit package, wherein the oscillator is suspended in the cavity using one or more supports protruding from a substrate.

In some aspects, the techniques described herein relate to an integrated circuit package, wherein the housing includes a metal.

In some aspects, the techniques described herein relate to an integrated circuit package, wherein the housing includes aluminum.

In some aspects, the techniques described herein relate to an integrated circuit package, wherein the housing includes contact pads electrically connected to the substrate.

In some aspects, the techniques described herein relate to an integrated circuit package, wherein the housing further includes insulating portions separating the contact pads.

In some aspects, the techniques described herein relate to an integrated circuit package, wherein a thickness of the housing is less than 1 mm.

In some aspects, the techniques described herein relate to an integrated circuit package, wherein a thickness of the housing is less than 0.5 mm.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of the preferred embodiments having reference to the attached figures, the invention not being limited to any particular embodiments disclosed.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of the preferred embodiments having reference to the attached figures, the invention not being limited to any particular embodiments disclosed.

### BRIEF DESCRIPTION OF THE DRAWINGS

These aspects and others will be apparent from the following description of preferred embodiments and the accompanying drawing, which is meant to illustrate and not to limit the invention, wherein:

FIG. 1 is a schematic side cross-sectional view of an example unprotected integrated device package with a housing forming a cavity around the module, according to one embodiment.

FIG. 2 is a schematic side cross-sectional view of an example deformed integrated device package due to a high-pressure encapsulation process, according to one embodiment.

FIG. 3 is a schematic side cross-sectional view of an example encapsulated protected device with a protection layer formed from a liquid component, according to one embodiment.

FIG. 4 is a schematic side cross-sectional view of an example encapsulated protected device with a protection layer formed from a liquid component and a solid component, according to one embodiment.

FIG. 5 is a schematic side cross-sectional view of another example encapsulated protected device with a protection layer formed from a liquid component and a solid component, according to one embodiment.

FIG. 6A shows a simulated deformation of an example unprotected housing, according to one embodiment.

FIG. 6B shows a simulated deformation of an example housing with a protection layer formed from a liquid component, according to one embodiment.

FIG. 6C shows a simulated deformation of an example housing with a protection layer formed from at least a solid component, according to one embodiment.

### DETAILED DESCRIPTION

Currently, pressure-sensitive integrated device packages are typically encapsulated through low-pressure molding processes, such as potting or Low Pressure Molding (LPM). However, compared to injection molding, low-pressure molding processes are developed for a narrower selection of materials, for example, certain adhesives. Furthermore, low-pressure molding processes usually produce a mold thickness of 1-2 mm over the entire encapsulated device. This makes it difficult to reduce the sizes of the products. Injection molding, on the other hand, offers more control and precision over the size and thickness of the molding material. In addition, injection molding using high pressure is better suited to form tight moisture and gas barriers between the encapsulated device and the environment compared to encapsulation formed under lower pressures. Some biocompatible plastic materials are better developed with injection molding processes. Moreover, injection molding can be more desirable when there is a size constraint, a material requirement (for example, biocompatible), or when a tight moisture/gas seal is required to protect the device from its environment (for example, medical devices and wearable devices).

Various embodiments disclosed herein relate to encapsulating an integrated device package, which may comprise one or more sensitive components such as a crystal oscillator or a semiconductor die, to protect the package against different environmental exposures.

According to various embodiments, a protection layer can be additionally formed on the integrated device package to shield integrated device packages from the pressure and stress of an encapsulation process. According to some embodiments, an integrated device package sensitive to pressure or stress may comprise a housing forming a sealed cavity around a semiconductor die. The housing may be prone to deformations that can affect the functionality of fragile components of the semiconductor die. For example, a metal lid of the housing may deform under the pressure and stress of a high-pressure encapsulation process, if the high-pressure encapsulation is directly formed over the integrated device package. The deformation of the housing may in turn cause strain or deformation of components internal to the package, and thereby negatively affect their functionality. For example, a housing deformed inward under elevated external pressure or stress may crash into fragile components such as a thin piece of crystal oscillator, changing its resonance frequency or even breaking the crystal, rendering the device inoperable.

Therefore, in various embodiments, a protection layer may be formed over the integrated device package as a mechanical shield by reducing the force that may otherwise be transmitted to the package. The protection layer may change the local force distribution transmitted to the surface of the integrated device package, for example, by absorbing or dispersing the pressure and stress. In various embodiments, the protection layer may be formed at a pressure or stress lower than that of the high-pressure molding process and may cause negligible or no deformation of the integrated device package. For example, according to some embodiments, a curable liquid may be applied in a flowable state to integrated device package and hardened into a hardened state, both under an ambient pressure. According to some embodiments, a solid component may also be attached to the integrated device package as part of the protection layer. During a subsequent high-pressure molding process, the protection layer may provide mechanical support to the housing of the integrated device package, preventing it from undesirable deformations or displacements. According to some embodiments, the protection layer may be formed on the integrated device package at a pre-molding assembly stage using automated equipment similar to those used for underfilling, potting, coating, dispensing, or pick and place operation, after which the protected integrated device package can be more reliably encapsulated or over-molded with high yield.

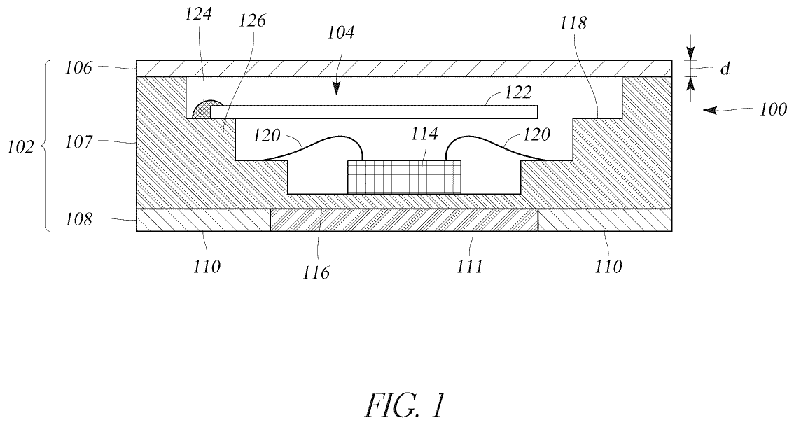

FIG. 1 is a schematic side cross-sectional view of an example unprotected integrated device package 100 comprising a housing 102 forming a sealed cavity 104 around a semiconductor die 114, according to one embodiment. The housing 102 of the integrated device package 100 may comprise a top side 106, a peripheral side 107 extending downward from the edges of the top side, and a bottom side 108 connected to the bottom of the peripheral side 107. The bottom side 108 of the housing may comprise a substrate, such as a printed circuit board (PCB), a ceramic substrate, or any other suitable package substrate. The bottom side 108 of the housing may be electrically connected to one or more electronic components inside the housing, including the semiconductor die. The bottom side 108 of the housing may further be electrically connected to electronic components external to the housing, thereby electrically connecting the integrated device package 100 to external components (not shown in FIG. 1). The one or more electronic components inside the housing may include, among others, a semiconductor die 114 and an oscillator 122. The semiconductor die 114 may be electrically connected to one or more ledges 118 protruding from the bottom side of the housing 108 through one or more bonding wires 120, for example, through bonding wires 120 connected to a top side of the semiconductor die 114. Though not explicitly illustrated, the semiconductor die 114 may additionally or alternatively be electrically connected to the bottom side of the housing 108 through pins, solder balls, or conductive pillars. In some embodiments, the oscillator 122 may be connected to the housing 102 or a substrate of the integrated device package using one or more oscillator joints 124, some of which may be electrically conductive.

Still referring to FIG. 1, a portion of the housing 102 of the integrated device package 100 may comprise a metal, such as aluminum, copper, brass, or steel. For example, the top side 106 of the housing may comprise a metal lid. Other portions of the housing may additionally comprise insulating materials, such as plastic or ceramic, or semiconductor materials. The top side 106 of the housing may comprise one or more malleable or fragile materials, for example, a metal or a plastic, and may be supported only at the edge by the peripheral sides 107. Therefore, the housing may be prone to deformation, especially at an unsupported center portion, under elevated external pressure and stress, for example, greater than 100 psi, 500 psi, 1000 psi or 2000 psi, 3000 psi, 4000 psi, 5000 psi, 6000 psi, or 8000 psi, 10000 psi, 20000 psi, or 30000 psi above atmospheric pressure. A thickness d of the housing may be less than 5 mm, 2 mm, 1 mm, 0.7 mm, 0.5 mm, 0.3 mm, 0.2 mm, 0.1 mm, or 0.05 mm, for example, 0.25 mm. A bottom side 108 of the housing may comprise an insulating portion 111 and one or more conductive portions 110. For instance, the bottom side 108 of the housing may comprise a substrate comprising an insulating material, metal contact pads, and traces. The metal contact pads and traces can be patterned either externally or internally to the insulating material. One or more conductive portion 110 may be disposed on a bottom surface of the integrated device package 100 and may be electrically connected to external circuits or devices, for example, to an external printed circuit board assembly (PCBA). In some embodiments, conductive pins, conductive pads, conductive pillars or solder may provide electrical contact between the housing 102 and external circuits or devices, and a gap may exist between the semiconductor die 114 and external circuits or devices due to the height of the electrical contacts. In some embodiments, the gap may be filled with a suitable underfill material. According to some embodiments, the bottom side of the housing 108 can include various types of circuitries that provide electrical connection among one or more electronic components of the integrated device package 100, and between the integrated device package 100 and external circuits or devices. As skilled artisans would appreciate, the circuitry of the bottom side of the housing 108 can be formed in single or multiple layers of conducting and dielectric materials, and various types of vias and traces between the layers of conducting materials.

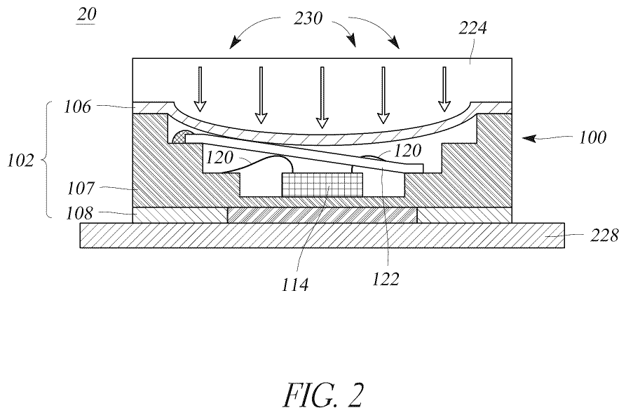

Still referring FIG. 1, the oscillator 122 may be a resonator, for instance, a piezoelectric resonator such as a crystal quartz resonator. The oscillator 122 may be provided in a flat, thin, or planar shape, for example, a thin circular slice of a flat material or a thin rectangular slice of a flat material. A mechanical resonance or the vibration of the oscillator 122 may be converted to a periodic, resonating, or oscillating electric signal and serves as a clock for the module. One or more oscillator joints 124 may be used to attach the oscillator 122 to one or more oscillator supports 126, such that the oscillator is suspended in a free space of the cavity 104. For example, as shown in FIG. 1, the oscillator 122 may be attached at one or more locations on its edge to the top of the oscillator support 126. The one or more oscillator supports 126 may protrude from the surface of the semiconductor die 114 and above other components of the die in the form of pillars, and may connect the oscillator 122 electrically to the rest of the die 114. The oscillator may occupy a majority of a cross-sectional area of the cavity 104, and be disposed to a side of the cavity 104 aside from other components of the semiconductor die 114. The oscillator also be disposed in parallel and immediately adjacent to a side of the housing a side of the housing 102, for example, parallel to and directly underneath the top side 106. The oscillator 122 may have a width greater than 30%, 50%, 70%, 80%, or 90% of the width of the cavity 104. Although such an arrangement can help make the integrated device package 100 compact, it may also make the oscillator vulnerable to deformation when the housing 100 deforms (see FIG. 2).

FIG. 2 is a schematic side cross-sectional view of an encapsulated deformed unprotected device 20, including a deformed integrated device package 100, as the result of forming an encapsulant 224 directly over the device, according to some embodiments. The encapsulated device may also comprise a completely or partially encapsulated printed circuit board (PCB) 228 connected to the integrated device package 100. Although not explicitly illustrated, PCB 228 may comprise circuitries in multiple layers of metal and dielectric materials and interconnecting vias and traces and may be further connected to other electronic components. The PCB 228 may be larger in size compared to the integrated device package 100. The integrated device package 100 may be electrically connected to the PCB 228 through the conductive portions 110 on the bottom of its housing 102. In some embodiments, a gap may exist between the integrated device package 100 and the PCB 228 which may be filled with a suitable underfill material.

According to various embodiments of the current disclosure, an encapsulation can be formed using injection molding. During an injection molding process, a device is positioned inside a hollow injection mold, and a viscous liquid encapsulant, for example, a molten plastic, is pumped at high pressure and high temperature to fill the inside of the injection mold, partially or completely covering the device. The high pressure used to form the encapsulation may be, for example, 0-100 psi, 100-500 psi, 500-1000 psi, 1000-2000 psi, 2000-3000 psi, 3000-4000 psi, 4000-5000 psi, 5000-6000 psi, 6000-8000 psi, 8000-10000 psi, or 10000-20000 psi above atmospheric pressure. The resulting encapsulation may be conformally fitted around the encapsulated device and may have a maximum thickness of less than 2 cm, 1 cm, 5 mm, 3 mm, 2 mm, 1.5 mm, 1 mm, 0.8 mm, 0.6 mm, 0.4 mm, 0.2 mm, 0.1 mm, or 0.05 mm. Encapsulation formed using high-pressure injection molding processes may have the advantages such as water-tight, moisture-tight, or gas-tight, or may be formed using a biocompatible material suitable to be used in a medical device or a wearable device. One or more of these advantages may not be available to encapsulation formed under lower pressures. After being injected into the mold and covering the device, the liquid encapsulant may then be allowed to solidify in a shape defined by the injection mold and form the encapsulation. Due to the viscosity of the liquid encapsulant, this process may put the device under a substantial level of high pressure, high shear stress, or high temperature. The external pressure and the shear stress, when applied to a surface of the device, are translated, respectively, into normal forces orthogonal to the surface of the housing and shear forces parallel to the surface of the housing, both of which may be capable of causing deformation or displacement of the various components of the device. The high temperature may help accelerate the deformation or displacement by softening portions of the device.

Still referring to FIG. 2, the encapsulant 224 may be formed partially or completely over the integrated device package 100 or the PCB 228 and is not limited to the shape and coverage illustrated in the figure. For example, the encapsulant may also be formed over at least a portion of the peripheral side 107 and the bottom side 108 of the integrated device package 100, or may continuously extend from the package 100 to cover at least a portion of the PCB 228. The encapsulation 224 may be formed conformally over the integrated device package 100 or the PCB and may be molded to have an irregular external surface profile depending on the specific needs of the encapsulated device.

As discussed herein, the integrated device package 100 may be exposed to pressure and stress 230 induced by the encapsulation material during an encapsulation process. Depending on its degree of contact with the encapsulation material, various portions of the integrated device package 100 may experience varying pressure and stress 230 with different magnitudes and orientations, for example, various portions of the housing 202, including but not limited to the top side 106, the peripheral side 107, and the bottom side 108 of the housing 102. As a result, different portions of the integrated device package 100 may experience different degrees of deformation. For illustrative purposes, only the top side 106 of the housing is shown with significant deformation or displacement. However, a skilled artisan would understand that the rest of the housing 202 including the peripheral side 107 or the bottom side 108 may also experience undesirable deformation or displacement due to encapsulation. As a result, the interior structures of the module may suffer deformation, displacement, or disconnection. For example, as shown in FIG. 2, the deformed top side of the housing 106 may crash into the oscillator 122, changing its electrical or mechanical properties, for example, its resonance frequency, or even breaking the crystal. The resulting deformed integrated device package 100 may experience unpredictable and undesirable modifications in various mechanical and electronic properties, resulting in unreliable and inefficient production processes.

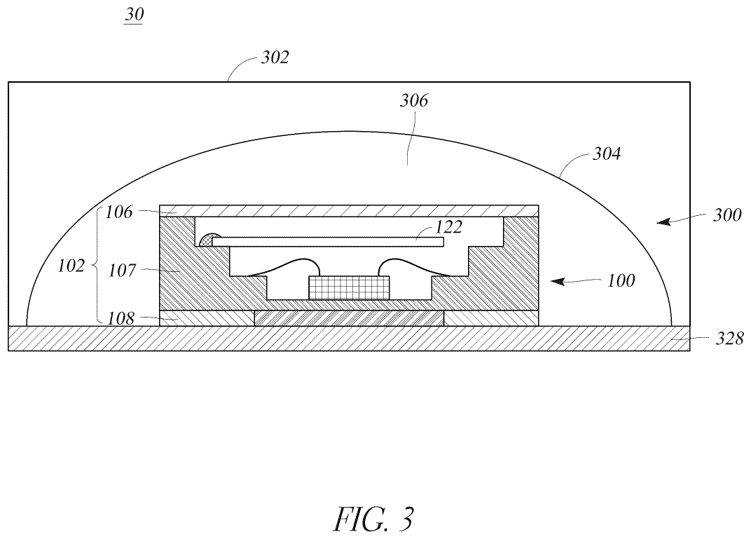

FIG. 3 is a schematic side cross-sectional view of an example encapsulated device 30 comprising an encapsulation layer 302 over a protected integrated device package 300, according to some embodiments. The outermost encapsulation layer 302 may share various features with the encapsulation layer 224 discussed with respect to FIG. 2, but may instead be partially or completely formed around the protected integrated device package 300 and a PCB 228 connected to the protected package 300. The protected package 300 may comprise a protection layer 304 formed partially or completely over an integrated device package 100 to protect it from external pressure and stress. As shown in FIG. 3, according to some embodiments, the protection layer 304 may comprise a solidified liquid component 306. The liquid component may be formed by first applying a curable liquid in a flowable state over the integrated device package 100 at a low pressure, and then solidifying or hardening the liquid through a curing process into a hardened state while maintaining a low pressure over the package. The low pressure at which the liquid component 306 is applied or cured may be lower than the pressure used to form the encapsulant 302, for example, lower than 5000 psi, 4000 psi, 3000 psi, 2000 psi, 1000 psi, 500 psi, 200 psi, 100 psi, 50 psi, 10 psi, or 1 psi above atmospheric pressure, and preferably lower than a pressure at which the integrated device package experiences any undesirable deformation, for instance, at an ambient atmospheric pressure. In some cases, the low pressure at which the liquid component 306 is applied or cured may be 4000-5000 psi, 3000-4000 psi, 2000-3000 psi, 1000-2000 psi, 500-1000 psi, 200-500 psi, 100-200 psi, 50-100 psi, 10-50 psi, 5-10 psi, 1-5 psi, or 0-1 psi above atmospheric pressure. In some cases, the low pressure at which the flowable state of the liquid component 306 is applied or cured may be between a vacuum pressure and an atmospheric pressure, for example, 0-15 psi, 0-10 psi, 0-5 psi, or 0-1 psi below an atmospheric pressure. According to some embodiments, the liquid component 306 can be both applied and cured into the hardened state at an atmospheric pressure. The encapsulant 302 disposed at least partially over the protection layer 304 may then be formed using high-pressure processes, such as injection molding, with a maximum thickness that is less than 2 cm, 1 cm, 5 mm, 3 mm, 2 mm, 1.5 mm, 1 mm, 0.8 mm, 0.6 mm, 0.4 mm, 0.2 mm, 0.1 mm, or 0.05 mm, or a value in a range defined by any of these values. The encapsulant 302 may also form a watertight, moisture-tight, or gas-tight barrier around the integrated device package 100, or may be formed using a biocompatible material suitable to be used in a medical device or a wearable device.

In some embodiments, the liquid component 306 may comprise an epoxy, a gel, an adhesive, a plastic, a sealant, or a potting material, for instance, Hysol® FP4450HF sold by LOCTITE® or a combination thereof in multiple stages. The protection layer 304 may be formed with or without using a mold. One or more layers of liquid components with different compositions may be applied and cured to form the protection layer 304. In some embodiments, the curable liquid may be applied in its flowable form using a transfer or shaping element such as a syringe, a pipet, a stick, a spray, or a brush. The curing process that hardens the liquid component into its hardened state may involve cooling, heating, drying, light exposure, a chemical bonding, or a chemical cross-linking process to harden or solidify the liquid component.

The hardened or solidified liquid component 306 may form the protection layer 304, shielding the integrated device package 100 from the pressure and stress during the formation of the encapsulation layer 302, by reducing the forces that may otherwise be transmitted to the integrated device package 100. It may do so by changing the local force distribution transmitted to the surface of the integrated device package, for example, by absorbing or dispersing the pressure and stress. According to some embodiments, the protection layer 304 may reduce a local pressure or stress that may otherwise be transmitted to the integrated device package 100 during a high-pressure encapsulation or over-molding process by more than 1%, 5%, 10%, 30%, 50%, 70%, 90%, 95%, 98%, 99%, 99.5%, 99.9%, or a value in a range defined by any of these values. According to some embodiments, the protection layer 304 may reduce a local deformation that may otherwise be experienced by the integrated device package 100 during a high-pressure encapsulation or over-molding process by more than 1%, 5%, 10%, 30%, 50%, 70%, 90%, 95%, 98%, 99%, 99.5%, 99.9%, or a value in a range defined by any of these values.

As shown by FIG. 3 In some embodiments, the protection layer 304 may form a barrier that completely separates the integrated device package 100 from the encapsulation 302. For example, when the integrated device package is connected to the PCB on the bottom side 108, the protection layer may be formed to cover the top side 106 and the peripheral side 107, such that the integrated device package 100 is entirely separated from the encapsulation 302 by the combination of the protection layer 304 and the PCB 228. According to some embodiments, the top side 106 of the housing may comprise a planar metal lid attached or adhered to the peripheral side 107, and the protection layer 304 may cover the exterior side of the metal lid completely. In some embodiments, the protection layer 304 may continuously extend from the surface of the integrated device package to the top surface of the PCB 228. In the cases where a gap exists between the integrated device package 100 and PCB 228, a suitable underfill material may be applied between the two, in direct contact with both the bottom side 108 of the package and the top side PCB 228. The liquid component can be applied before or after the integrated device package 100 is attached to the PCB 228 depending on the production process. In some embodiments, the protection layer 304 may only form a partial barrier that separates the most pressure-sensitive portion of the integrated device package 100 from the encapsulation 302. A pressure-sensitive portion of the integrated device package 100 can be where pressure-sensitive or fragile internal components, such as an oscillator, are located. For example, the protection layer 304 may be formed to cover only the top side 106 of the housing, near where the oscillator 122 is located, and leave the peripheral side 107 of the integrated device package exposed to the encapsulation layer 302. In some embodiments, when the protection layer 304 is formed from a liquid component 306 in free space, it may develop a smooth, convex exterior profile defined by the surface tension of the uncured liquid in air. The protection layer 304 may form a shape similar to a droplet (e.g., a convex domed shape) around the integrated device package 100.

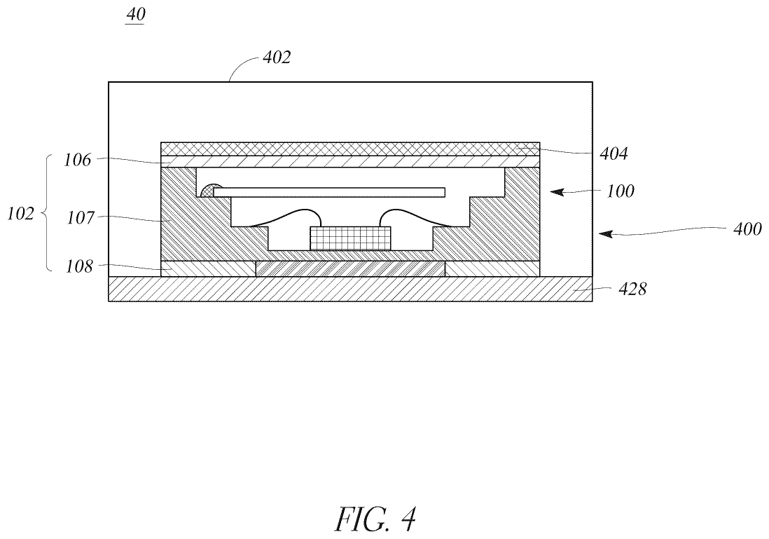

FIG. 4 is a schematic side cross-sectional view of an example encapsulated device 40 comprising an encapsulation layer 402 over a protected integrated device package 400, according to some embodiment. The outermost encapsulation layer 402 may share various features with the encapsulation layer 224 discussed with respect to FIG. 2 but may instead be partially or completely formed around the protected integrated device package 400 and a PCB 228 connected to the package. The protected package 400 may comprise a protection layer 404 formed partially or completely over an integrated device package 100 to protect it from external pressure and stress. As shown in FIG. 4, according to some embodiments, the protection layer 404 may comprise a solid component attached to the integrated device package 100, for example, using an adhesive. According to some embodiments, the solid component may be attached to the integrated device package using the adhesive in a flowable state at a low pressure, and the adhesive hardened or solidified into a hardened state in a curing process while maintaining the low pressure, thereby forming the protection layer 404. The low pressure with which the protection layer 404 is formed may be lower than the pressure used to form the encapsulation layer 402, for example, lower than 1000 psi, 500 psi, 200 psi, 100 psi, 50 psi, 10 psi, or 1psi above atmospheric pressure, and preferably lower than a pressure at which the integrated device package experiences any undesirable deformation, for instance, at an ambient atmospheric pressure. In some cases, the low pressure at which the protection layer 404 is applied or cured may be 4000-5000 psi, 3000-4000 psi, 2000-3000 psi, 1000-2000 psi, 500-1000 psi, 200-500 psi, 100-200 psi, 50-100 psi, 10-50 psi, 5-10 psi, 1-5 psi, or 0-1 psi above atmospheric pressure. In some cases, the low pressure at which the protection layer 404 is applied or cured may be between a vacuum pressure and an atmospheric pressure, for example, 0-15 psi, 0-10 psi, 0-5 psi, or 0-1 psi below an atmospheric pressure. According to some embodiments, the adhesive can be applied or cured at an atmospheric pressure. The encapsulant 402 disposed at least partially over the protection layer 404 may then be formed using a high-pressure process, such as injection molding, with a maximum thickness that is less than 2 cm, 1 cm, 5 mm, 3 mm, 2 mm, 1.5 mm, 1 mm, 0.8 mm, 0.6 mm, 0.4 mm, 0.2 mm, 0.1 mm, or 0.05 mm, or a or a value in a range defined by any of these values. The encapsulant 402 may also form a watertight, moisture-tight, or gas-tight barrier around the integrated device package 100, or may be formed using a biocompatible material suitable to be used in a medical device or a wearable device.

According to some embodiments, the protection layer 404 may reduce a local pressure or stress that may otherwise be transmitted to the integrated device package 100 during a high-pressure encapsulation or over-molding process by more than 1%, 5%, 10%, 30%, 50%, 70%, 90%, 95%, 98%, 99%, 99.5%, 99.9%, or a value in a range defined by any of these values. According to some embodiments, the protection layer 404 may reduce a local deformation that may otherwise be experienced by the integrated device package 100 during a high-pressure encapsulation or over-molding process by more than 1%, 5%, 10%, 30%, 50%, 70%, 90%, 95%, 98%, 99%, 99.5%, 99.9%, or a value in a range defined by any of these values.

In some embodiments, a solid component of the protection layer 404 may be attached or adhered to the integrated device package 100, for example, attached or adhered to the integrated device package 100. The solid component may comprise a planar element, such as a plate or a flat slab of solid material, disposed against and parallel to an external surface, for example, an external top surface, of the integrated device package 100. As shown in FIG. 4, a width or area of the solid component may be approximately equal to or larger than those of the integrated device package 100, and the solid component may be arranged directly on top of the integrated device package such that it completely shields the package from the top. In some embodiments, although not explicitly illustrated, a width or area of the solid component may be also be smaller than a width or area of the integrated device package 100, for example, the planar element may cover 30%-100%, 50%-100%, 70%-100%, or 90%-100%. In some embodiments, the planar element may partially or completely cover the peripheral side 107 or the top side 106 of the integrated device package 100. of the area of the top side 106 of the integrated device package, shielding selected portions of the package that is most vulnerable to deformation under pressure or stress, saving the solid material and compactifying the arrangement. When a PCB 228 is attached to the bottom side of the integrated device package 100, the solid component of the protection layer 404 may be attached to the top side of the integrated device package 100 opposite from the side to which PCB 228 is attached, such that the integrated device package is disposed between the solid component and the PCB.

Although not explicitly illustrated in FIG. 4, according to some embodiments, one or more solid components may additionally or alternatively be attached to the peripheral side 107 or the bottom side 108 of the integrated device package 100. More than one piece of solid components may be attached to the integrated device package 100 on the same or different external surfaces of the integrated device package 100. A solid component may be attached to a plurality of integrated device packages, and to other electronic components connected to the PCB in addition to the integrated device package. The solid component may have a higher Young's module than that of the housing of the integrated device package. For example, when subjected to the same pressure or stress, the solid component may deform or displace less than the housing 102. The solid component of the protection layer 404 may comprise a ceramic, a semiconductor, a plastic, or a metal, for instance, a silicon slab or plate, and may have a thickness larger than 0.1 mm, 0.5 mm, 0.75 mm, 1 mm, 1.25 mm, 1.5 mm, 2 mm, 3 mm, or 5 mm. In some cases, the protection layer 404 may have a Young's modulus of 0.01-0.1 GPa, 0.1-1 GPa, 1-5 GPa, 5-10 GPa, 10-100 GPa, 100-400 GPa, 400-8000 GPa, or 8000-1200 GPa. In some cases, for example, the protection layer 404 may comprise acrylic, or may have a Young's modulus of approximately 0.001-1200 GPa, 0.01-500 GPa, 0.1-100 GPa, 0.5-50 GPa, 1-10 GPa, 2-4 GPa, for instance, approximately 3.2 GPa. In some cases, for example, the protection layer 404 may comprise silicon, or may have a Young's modulus of approximately 0.01-1200 GPa, 0.1-1000 GPa, 1-700GPa, 10-500 GPa, 50-300 GPa, 100-250 GPa, 120 GPa-210 GPa, 150-190 GPa, for instance, approximately 170 GPa. In some embodiments, the adhesive may share various features with the liquid component 306 discussed with respect to FIG. 3.

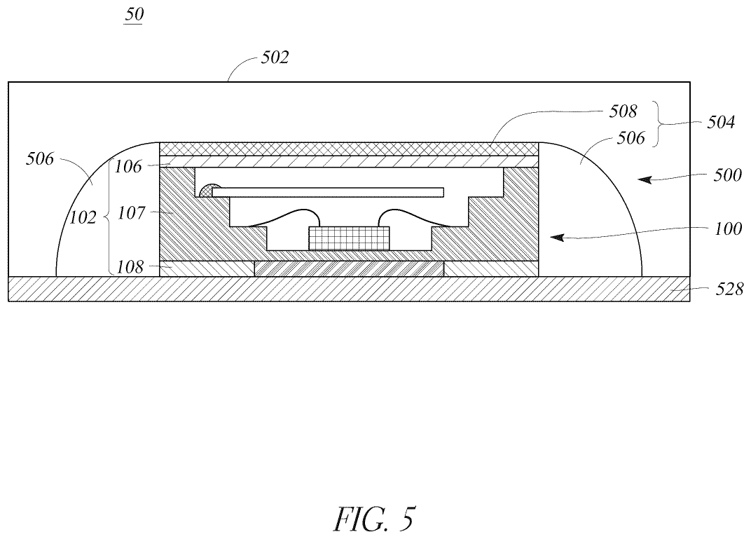

Still referring to FIG. 4, as mentioned above, a liquid adhesive may be applied and cured between the solid component of the protection layer 404 and the integrated device package 100. The liquid adhesive may share various properties with the liquid component 306 of the embodiment from FIG. 3. In some embodiments, an adhesive element may also be applied to portions of the integrated device package 100 not directly shielded by the solid component and provide extra mechanical support to these exposed portions. For instance, as illustrated in the embodiment shown in FIG. 5, a liquid component 506 may be applied to the peripheral side 107 of the integrated device package 100 and cured with a solid component 508 disposed on the top side of the package. In addition to helping attach the solid component 508 to the integrated device package 100, the liquid component 506 may also provide mechanical support to the peripheral surfaces that are not directly shielded by the solid component, and further disperse the pressure and stress away from the integrated device package.

The encapsulated protected device 50 of FIG. 5 may share various components and features similar to those discussed with respect to FIG. 3 and FIG. 4, the details of which are omitted here for brevity. As shown in FIG. 5, the solid component 508 may be disposed on top side 106 integrated device package 100 with no liquid component between them. For example, the solid component 508 may be disposed in direct contact with a metal lid of the integrated device package 100. In this case, the solid component 508 and the integrated device package 100 may be attached to each other by both being in direct contact with the solidified liquid component 506. In some embodiments, although not explicitly illustrated, the solid component 508 may also be attached to the integrated device package 100 with a layer of adhesive or liquid component 406 between the two, similar to the embodiment illustrated in FIG. 4, in addition to being attached to each other by the liquid component 506 from the side. A Young's modulus of the solid component 508 may be higher than the Young's modulus of the housing 102 of the integrated device package and the Young's modulus of the solidified liquid component 506. For example, when subjected to the same pressure or stress, the solid component may deform less than the housing 102 or the solidified liquid component 506. The liquid component 506 may form on all the surfaces of the integrated device package 100 that are not directly covered by the solid component 508 or the PCB 228. According to some embodiments, the protection layer 504 may reduce a local pressure or stress that may otherwise be transmitted to the integrated device package 100 during a high-pressure encapsulation or over-molding process by more than 1%, 5%, 10%, 30%, 50%, 70%, 90%, 95%, 98%, 99%, 99.5%, 99.9%, or a value in a range defined by any of these values. According to some embodiments, the protection layer 504 may reduce a local deformation that may otherwise be experienced by the integrated device package 100 during a high-pressure encapsulation or over-molding process by more than 1%, 5%, 10%, 30%, 50%, 70%, 90%, 95%, 98%, 99%, 99.5%, 99.9%, or a value in a range defined by any of these values.

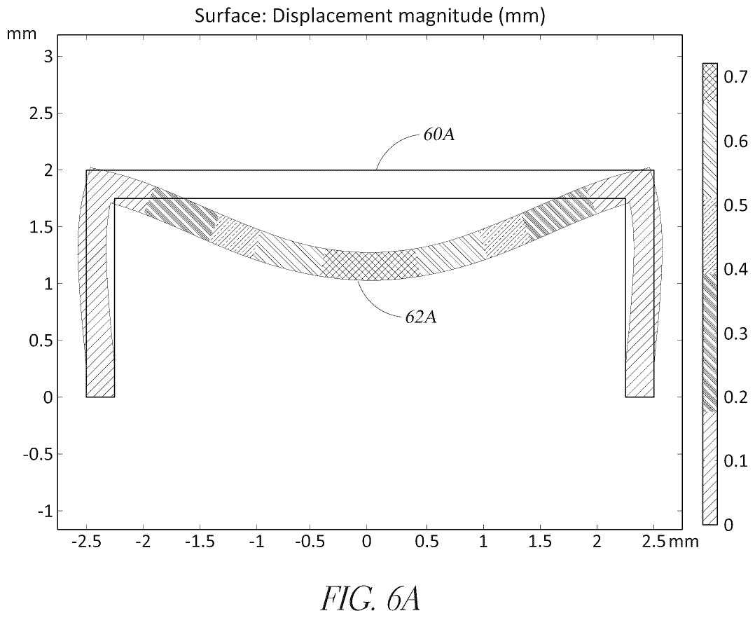

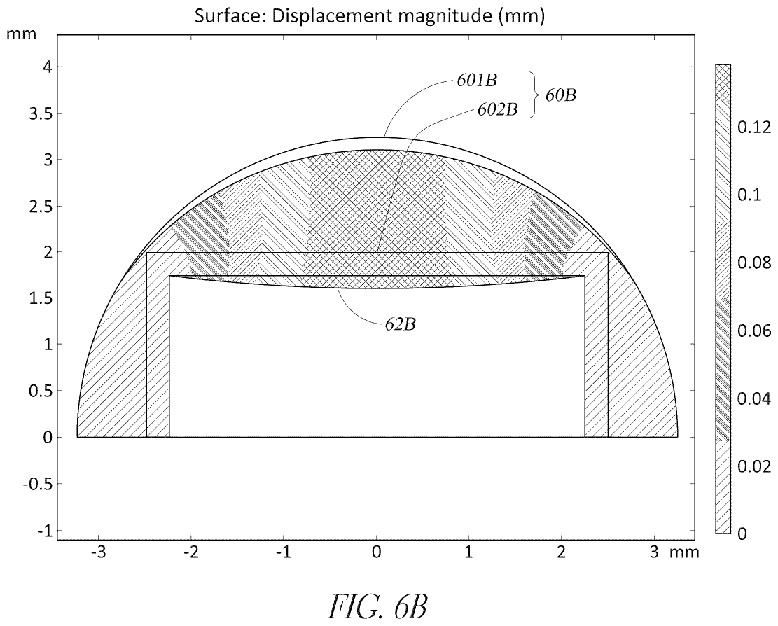

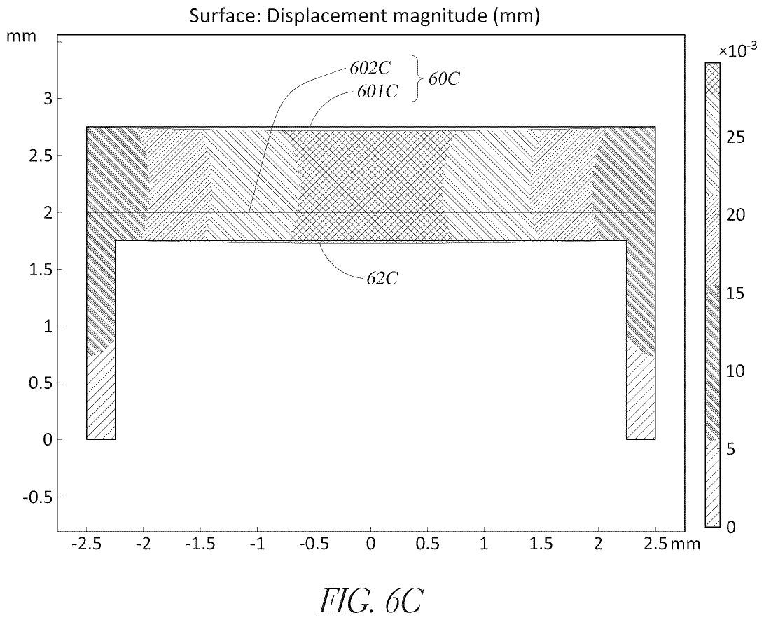

FIGS. 6A-6C show simulated deformation results of a typical housing with various levels of protection under elevated pressure, which may be representative of a steady-state result of the simulated system, or a state of the system a sufficiently long time after an initial state. The black outlines, 60A, 60B, and 60C in FIGS. 6A-6C represents the cross-sectional shape of various housings before a pressure of 5000 psi is applied to the exterior of the housing, for instance, from above, among which 60A is an unprotected housing, and 60B and 60C are protected housings covered with different types of protection layers. The bottom outline of the protected housings 62B and 62C represents unprotected housing similar to 60A, and the top outline of the protected housings 61B and 61C represents different types of protection layers. In the simulations of FIGS. 6A-6C, each of the unprotected housings 60A, 601B, and 601C comprises a planar or flat top side with a lateral dimension of 5 mm in width and a suitable size in depth, for example, a unit length, and four vertical planar walls extending vertically downward from the top side with a height of 2 mm. The thickness of both the top sides and the walls of the unprotected housings is 0.25 mm. The unprotected housing is simulated as a bottomless housing, with the bottom of the walls rigidly attached to an imaginary non-deformable surface. This imaginary surface and the interior of the housing define a cavity with a rectangular vertical cross-section. The simulation parameters of the deformation of the unprotected housing are based on the mechanical properties of a typical aluminum material. The hatched shapes 62A, 62B, and 62C represent the cross-sectional profile of the deformed housings after a pressure of 5000 psi is applied to the exterior of the housings 60A, 60B, and 60C, with the various hatching representing the magnitude of the local displacement from the original location experienced by various portions of the housing.

FIG. 6A shows a simulated deformation 62A of an unprotected housing 60A. For example, the hatched shape 62A represents the deformation experienced by an unprotected housing 60A when a pressure of 5000 psi, similar to the pressure of a high-pressure encapsulation process, is directly applied to the external surface of the housing. As one can see, the middle portion of the housing experiences the most severe deformation from the original shape, with a maximum displacement of 0.72 mm. Visible outward bulging, or buckling, can also be observed on the sidewalls.

FIG. 6B shows a simulated deformation 62B of a protected housing 60B comprising a spherical or droplet-shaped protection layer 601B similar to that discussed with respect to FIG. 3. The protection layer 601B is formed on the exterior surface of the unprotected housing 602B. The simulation parameters of the protection layer 601B are based on the mechanical properties of a typical cured liquid component similar to those discussed herein. For example, the mechanical properties of the protection layer 601B may be similar to that of a solidified liquid component such as 306, 406, or 506 from FIGS. 3, 4, or 5, respectively. In some cases, for example, the protection layer 601B may comprise acrylic, or may have a Young's modulus of 1-5 GPa, for instance, approximately 3.2 GPa. In some cases, for example, the unprotected housing 602B may comprise aluminum, or may have a Young's modulus of approximately 10-120 GPa, for instance, approximately 70 GPa. The connection at the boundary of the housing 602B and the protection layer 601B is set such that no slipping or detachment is allowed. The boundary condition is an idealized presentation of the device, and in real life, microscopic or macroscopic slipping or detachment may take place between an integrated device package and its protection layer during both manufacturing or usage of the device. The hatched shape 62B represents the deformation experienced by the protected housing 60B when a pressure of 5000 psi is directly applied to the external surface of the protected housing 60B, for example, to the external surface of the protection layer 601B. According to the simulation, the deformation 62B experienced by the protected housing is significantly smaller than that of the unprotected housing 62A from FIG. 6A, indicating a significant reduction of force experienced by the unprotected housing 602B underneath the protection layer 601B. The middle portion of the top side of protected housing still experiences the largest local displacement of 0.14 mm. However, the deformation of the sidewalls is no longer visible at the scale shown by the plot.

FIG. 6C shows a simulated deformation 62C of a protected housing 60C comprising a protection layer 601C similar to that discussed with respect to FIGS. 4 and 5. The protection layer 601C is formed on the exterior surface of the unprotected housing 602C. The simulation parameters of the protection layer 601C are based on the mechanical properties of a solid component similar to those discussed herein. For example, the mechanical properties of the protection layer 601C may be similar to that of silicon, or may have a Young's modulus of approximately 120-190 GPa, for instance, of approximately 170 GPa. The connection at the boundary of the housing 602C and the protection layer 601C is set such that no slipping or detachment is allowed. Applicant would like to point out that this boundary condition is an idealized presentation of the device, and that in real life, microscopic or macroscopic slipping or detachment may take place between an integrated device package and its protection layer during both manufacturing or usage of the device. The hatched shape 62C represents the deformation experienced by the protected housing 60C when a pressure of 5000 psi is applied to the external surface of the protected housing 60C, for example, to the external surface of the protection layer 601C. As one can see, the deformation 62C experienced by the unprotected housing 60C is the smallest among the results shown in FIGS. 6A-6C. A small displacement of 0.03 mm can be observed at the middle portion of the top side of the protected housing, indicating an almost negligible amount of force experienced by the unprotected housing 602C underneath the protection layer 601C. The deformation of the sidewalls is again not visible at the scale shown by the plot.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

Several illustrative examples of encapsulated integrated device packages have been disclosed. Although this disclosure has been described in terms of certain illustrative examples and uses, other examples and other uses, including examples and uses which do not provide all of the features and advantages set forth herein, are also within the scope of this disclosure. Components, elements, features, acts, or steps may be arranged or performed differently than described and components, elements, features, acts, or steps may be combined, merged, added, or left out in various examples. All possible combinations and subcombinations of elements and components described herein are intended to be included in this disclosure. No single feature or group of features is necessary or indispensable.

Certain features that are described in this disclosure in the context of separate implementations may also be implemented in combination in a single implementation. Conversely, various features that are described in the context of a single implementation also may be implemented in multiple implementations separately or in any suitable subcombination. Moreover, although features may be described above as acting in certain combinations, one or more features from a claimed combination may in some cases be excised from the combination, and the combination may be claimed as a subcombination or variation of a subcombination.

Further, while illustrative examples have been described, any examples having equivalent elements, modifications, omissions, and/or combinations are also within the scope of this disclosure. Moreover, although certain aspects, advantages, and novel features are described herein, not necessarily all such advantages may be achieved in accordance with any particular example. For example, some examples within the scope of this disclosure achieve one advantage, or a group of advantages, as taught herein without necessarily achieving other advantages taught or suggested herein. Further, some examples may achieve different advantages than those taught or suggested herein.

Some examples have been described in connection with the accompanying drawings. The figures may or may not be drawn and/or shown to scale, but such scale should not be limiting, since dimensions and proportions other than what are shown are contemplated and are within the scope of the disclosed invention. Distances, angles, etc. are merely illustrative and do not necessarily bear an exact relationship to actual dimensions and layout of the devices illustrated. Components may be added, removed, and/or rearranged. Further, the disclosure herein of any particular feature, aspect, method, property, characteristic, quality, attribute, element, or the like in connection with various examples may be used in all other examples set forth herein. Additionally, any methods described herein may be practiced using any device suitable for performing the recited steps.

For purposes of summarizing the disclosure, certain aspects, advantages and features of the inventions have been described herein. Not all, or any such advantages are necessarily achieved in accordance with any particular example of the inventions disclosed herein. No aspects of this disclosure are essential or indispensable. In many examples, the devices, systems, and methods may be configured differently than illustrated in the figures. or description herein. For example, various functionalities provided by the illustrated modules may be combined, rearranged, added, or deleted. In some implementations, additional or different processors or modules may perform some or all of the functionalities described with reference to the examples described and illustrated in the figures. Many implementation variations are possible. Any of the features, structures, steps, or processes disclosed in this specification may be included in any example.

What is claimed is:

1. A method for manufacturing an integrated circuit package, the method comprising:
providing a substrate;
providing an integrated device package mounted to the substrate; and
forming a protection layer at least partially over the integrated device package by applying a first liquid to the integrated device package and hardening the first liquid at a first pressure less than 1000 psi relative to an atmospheric pressure.

2. The method of claim 1, wherein the method further comprises forming an encapsulant at least partially over the protection layer at a second pressure higher than the first pressure.

3. The method of claim 2, wherein forming the encapsulant comprises forming the encapsulant using injection molding.

4. The method of claim 2, wherein the second pressure is at least 1000 psi above an atmospheric pressure.

5. The method of claim 1, wherein forming the protection layer further comprises attaching a solid element to the integrated device package using the first liquid, wherein the solid element has a higher Young's modulus than that of the hardened first liquid.

6. The method of claim 1, wherein the integrated device package comprises a housing defining a cavity.

7. The method of claim 6, wherein the housing defines the cavity around a piezoelectric oscillator configured to output a periodic electrical signal.

8. An integrated circuit package, comprising:
a substrate;
an integrated device package mounted to the substrate; and
a protection layer disposed at least partially over the integrated device package, the protection layer comprising a solid element attached to the integrated device package at a first pressure.

9. The integrated circuit package of claim 8, further comprising an encapsulant disposed at least partially over the protection layer, the encapsulant formed at a second pressure higher than the first pressure.

10. The integrated circuit package of claim 8, wherein the solid element is planar shaped.

11. The integrated circuit package of claim 8, wherein the protection layer further comprises a first liquid applied to the integrated device package and hardened at the first pressure, wherein the first liquid is configured to attach the solid element to the integrated device package.

12. The integrated circuit package of claim 11, wherein the solid element has a higher Young's modulus than that of the hardened first liquid.

13. The integrated circuit package of claim 8, wherein the solid element comprises a ceramic, a semiconductor, or silicon.

14. The integrated circuit package of claim 8, wherein an area of the solid element is at least 30% of an area of the integrated device package.

15. The integrated circuit package of claim 9, wherein the encapsulant is configured to form a water-tight or a gas-tight barrier over the integrated device package.

16. The integrated circuit package of claim 8, wherein the integrated device package comprises a housing defining a cavity.

17. The integrated circuit package of claim 16, wherein the housing defines the cavity around a piezoelectric oscillator configured to output a periodic electrical signal.

18. The integrated circuit package of claim 16, wherein a thickness of the housing is less than 1 mm.

19. An integrated circuit package, comprising:
a substrate;
an integrated device package mounted to the substrate; and
a protection layer disposed at least partially over the integrated device package, the protection layer comprising a first component, wherein the first component comprises a first material,
wherein the first material has a flowable state in which the first material is configured to flow over the integrated device package at a first pressure,
wherein the first material further comprises a hardened state formed by hardening the flowable state at the first pressure, and
wherein the first component comprises the first material in the hardened state; and
an encapsulant formed at least partially over the protection layer at a second pressure higher than the first pressure.

20. The integrated circuit package of claim 19, wherein the protection layer further comprises a second component, the second component comprising a second solid material attached to the integrated device package at the first pressure using the first material.
